(19) United States
(12) Patent Application Publication
(10) Pub. No.: US 2019/0097071 A1
(43) Pub. Date: Mar. 28, 2019

(54) ENCAPSULANT MATERIAL FOR PHOTOVOLTAIC MODULES AND METHOD OF PREPARING THE SAME

(71) Applicants: TIGER NEW SURFACE MATERIALS (SUZHOU) CO., LTD., Suzhou (CN); SUNMAN (SHANGHAI) CO., LTD., Shanghai (CN)

(72) Inventors: Tianhe DAI, Suzhou (CN); Biao LUO, Suzhou (CN); Zhicheng WANG, Suzhou (CN); Guozhu LONG, Shanghai (CN); Jiaoyan LIU, Shanghai (CN); Chengrong LIAN, Shanghai (CN); Weili WANG, Shanghai (CN)

(21) Appl. No.: 16/198,863

(22) Filed: Nov. 22, 2018

Related U.S. Application Data
(63) Continuation-in-part of application No. PCT/CN2017/072150, filed on Jan. 23, 2017.

(30) Foreign Application Priority Data
Aug. 18, 2016 (CN) 201610685240.9

(51) Int. Cl. H01L 31/048; D06N 3/12; D06N 3/00

(52) U.S. Cl. CPC H01L 31/0481; D06N 2209/1692; D06N 3/0006; D06N 3/123

(57) ABSTRACT

An encapsulant material for a photovoltaic module. The encapsulant material includes: between 30 and 50 parts by weight of fiber cloth, and between 50 and 70 parts by weight of a polyester powder coating. The polyester powder coating includes a polyester resin and a curing agent. The polyester resin is a polymer of monomers selected from terephthalic acid, m-phthalic acid, neopentyl glycol, adipic acid, ethylene glycol, or a mixture thereof. The curing agent accounts for 2-20 wt. % of the polyester powder coating. The polyester powder coating is evenly distributed on the fiber cloth. A method of preparing the packaging material includes: evenly distributing the polyester powder coating on the fiber cloth using a coating device; and thermally bonding the polyester powder coating and the fiber cloth.

### CROSS-REFERENCE TO RELATED APPLICATIONS

This application is a continuation-in-part of International Patent Application No. PCT/CN2017/072150 with an international filing date of Jan. 23, 2017, designating the United States, now pending, and further claims foreign priority benefits to Chinese Patent Application No. 201610685240.9 filed Aug. 18, 2016. The contents of all of the aforementioned applications, including any intervening amendments thereto, are incorporated herein by reference.

### BACKGROUND

This disclosure relates to the photovoltaic field, and more particularly, to an encapsulant material for photovoltaic (PV) modules and a method of preparing the same.

Conventional photovoltaic modules used in the photovoltaic field are bulky. As shown in FIG. 5, the encapsulant structure of conventional photovoltaic modules includes, from top to bottom, a tempered glass layer 30c, an upper ethylene-vinyl acetate (EVA) layer 21c, a photovoltaic cell layer 10c, a lower EVA layer 22c, and a backsheet layer 40c. The density of the tempered glass layer reaches 2.5 g/cm³, and the normal thickness of the tempered glass layer is 3.2 mm. Therefore, the tempered glass weights up to 8 kg per square meter, and the photovoltaic modules packaged in the encapsulant structure are bulky and difficult to install.

Currently, highly transparent films and/or transparent backsheets are used to replace the tempered glass to reduce the weight of the photovoltaic modules. However, because most of the highly transparent films and transparent backsheets are made of adhesive films such as ethylene-vinyl acetate (EVA) copolymer and poly(octene-ethylene) (POE), the encapsulated photovoltaic modules do not meet the technical requirements of the photovoltaic industry in terms of impact resistance and fire resistance.

### SUMMARY

Disclosed is an encapsulant material for photovoltaic module that is inexpensive, light-weighted, can meet the technical standards of the photovoltaic industry such as UV resistance, anti-aging, impact resistance, fire prevention and the like.

Also disclosed is a method of preparing an encapsulant material for a photovoltaic module.

Disclosed is an encapsulant material for a photovoltaic module, the encapsulant material comprising: between 30 and 50 parts by weight of a fiber cloth; and between 50 and 70 parts by weight of a polyester powder coating, the polyester powder coating comprising a polyester resin and a curing agent, and the polyester powder coating being evenly distributed on the fiber cloth.

The weight per unit area of the fiber cloth can be 30-400 g/m², and the weight per unit area of the polyester powder coating distributed on the fiber cloth can be 100-400 g/m².

The fiber cloth can comprise a fiber material selected from glass fiber, carbon fiber, aramid fiber, or a mixture thereof.

The monofilament diameter of the fiber material can be between 3 and 23 μm.

The fiber cloth can be in the form of a plain weave, a twill weave, a satin weave, a rib weave, a mat weave, or a combination thereof.

The polyester resin can be a hydroxyl polyester resin, a carboxyl polyester resin, or a mixture thereof.

The polyester resin can be a polymer of monomers selected from terephthalic acid, m-phthalic acid, neopentyl glycol, adipic acid, ethylene glycol, or a mixture thereof.

The polyester resin can be a hydroxyl polyester resin comprising between 30 and 300 mg of KOH per gram of the hydroxyl polyester resin; a glass transition temperature of the hydroxyl polyester resin is between 50 and 75° C., and a viscosity of the hydroxyl polyester resin is between 15 and 200 Pa·s

The polyester resin can be a carboxyl polyester resin comprising between 15 and 85 mg of KOH per gram of the carboxyl polyester resin; a glass transition temperature of the carboxyl polyester resin is between 50 and 75° C., and a viscosity of the carboxyl polyester resin is between 15 and 200 Pa·s.

The curing agent can account for 2-20 wt. % of the polyester powder coating, and the curing agent can be 1,3,5-triglycidyl isocyanurate, triglycidyl trimellitate (TML), diglycidyl terephthalate, glycidyl methacrylate (GMA), hydroxyalkyl amide, isocyanate, or a mixture thereof.

The polyester powder coating can further comprise a coating additive; the coating additive can account for 0-40 wt. % of the polyester powder coating, and the coating additive can be polyamide wax, polyolefine wax, amide modified phenolic urea surfactant, benzoin, poly(dimethylsiloxane), vinyl trichlorosilane, n-butyl triethoxyl silane, tetramethoxysilane (TMOS), monoalkoxy pyrophosphate, acrylics, phenolic resin, urea-formaldehyde resin, melamine formaldehyde resin, distearoyl ethylenediamine, a mixture of ethylene oxide and propylene oxide, hindered phenol, thiodipropionate, diphenyl ketone, salicylate derivatives, hindered amine, alumina, fumed silica, tetrabromobisphenol A, decabromodiphenyl ethane, tricresyl phosphate, aluminum hydroxide, magnesium hydroxide, barium sulfate, titanium dioxide, carbon black, or a mixture thereof.

Further disclosed is a method of preparing an encapsulant material for a photovoltaic module, the method comprising:
1) evenly distributing the polyester powder coating on the fiber cloth using a coating device; and
2) thermally bonding the polyester powder coating and the fiber cloth.

The method can further comprises piecewise cutting a resulting product obtained by thermally bonding the polyester powder coating and the fiber cloth in 2).

Thermally bonding the polyester powder coating and the fiber cloth can be implemented with the following parameters: a pressure is between 0.05 and 0.25 megapascal, a temperature is between 90 and 130° C., and a heating time is between 5 and 20 seconds.

The encapsulant material for a photovoltaic module of the disclosure comprises between 30 and 50 parts by weight of a fiber cloth and between 50 and 70 parts by weight of a polyester powder coating which is evenly distributed on the fiber cloth. The encapsulant material meets the technical standards of the photovoltaic industry such as UV resistance, anti-aging, impact resistance, fire prevention and the like, and is inexpensive, light-weighted, can replace the tempered glass of conventional encapsulant structure, and provide rigidity for the photovoltaic module to protect the photovoltaic cells. Thus, the weight of the photovoltaic module is greatly reduced, which facilitates the installation of the photovoltaic module in different occasions, reduces the labor intensity for installing the photovoltaic module, improves the convenience of installation, and reduces the installation cost of the photovoltaic module.

The preparation method of the encapsulant material comprises evenly distributing the polyester powder coating on the fiber cloth, thermally bonding the polyester powder coating and the fiber cloth, and then piecewise cutting a resulting product obtained by thermally bonding the polyester powder coating and the fiber cloth, to yield the encapsulant material. The dimensions of the PV module can be changed arbitrarily to meet the installation requirements of different buildings, which further facilitates the installation and application of the PV module.

### BRIEF DESCRIPTION OF THE DRAWINGS

FIG. 1 is a flow chart of a method of preparing an encapsulant material for a photovoltaic module in the disclosure;

FIG. 2 is schematic diagram of a device for preparing an encapsulant material for a photovoltaic module in the disclosure;

FIG. 3 is a schematic diagram of an encapsulant structure of a photovoltaic module using the encapsulant material in the disclosure;

FIG. 4 is another schematic diagram of an encapsulant structure of a photovoltaic module using the encapsulant material in the disclosure; and

FIG. 5 is a schematic diagram of an encapsulant structure of a photovoltaic module in the prior art.

### DETAILED DESCRIPTION

The disclosure provides an encapsulant material for a photovoltaic module, the encapsulant material comprising: between 30 and 50 parts by weight of a fiber cloth, the fiber cloth being formed by fiber material; and between 50 and 70 parts by weight of a polyester powder coating, the polyester powder coating comprising a polyester resin and a curing agent, and the polyester powder coating being evenly distributed on the fiber cloth.

The encapsulant material for a photovoltaic module of the disclosure comprises between 30 and 50 parts by weight of a fiber cloth and between 50 and 70 parts by weight of a polyester powder coating which is evenly distributed on the fiber cloth. The encapsulant material meets the technical standards of the photovoltaic industry such as UV resistance, anti-aging, impact resistance, fire prevention and the like, and is inexpensive, light-weighted, can replace the tempered glass of conventional encapsulant structure, and provide rigidity for the photovoltaic module to protect the photovoltaic cells. Thus, the weight of the photovoltaic module is greatly reduced, which facilitates the installation of the photovoltaic module in different occasions, reduces the labor intensity for installing the photovoltaic module, improves the convenience of installation, and reduces the installation cost of the photovoltaic module.

The disclosure also provides a method of preparing an encapsulant material for a photovoltaic module, the method comprising:

1) evenly distributing the polyester powder coating on the fiber cloth; and

2) thermally bonding the polyester powder coating and the fiber cloth.

The method further comprises piecewise cutting a resulting product obtained by thermally bonding the polyester powder coating and the fiber cloth in 2).

The preparation method of the encapsulant material comprises evenly distributing the polyester powder coating on the fiber cloth, thermally bonding the polyester powder coating and the fiber cloth, and then piecewise cutting a resulting product obtained by thermally bonding the polyester powder coating and the fiber cloth, to yield the encapsulant material. The dimensions of the PV module can be changed arbitrarily to meet the installation requirements of different buildings, which further facilitates the installation and application of the PV module.

To more clearly explain the embodiments of the disclosure or the technical solutions in the prior art, the drawings used in the description of the embodiments or the prior art will be briefly described below. Obviously, the drawings in the following description are only some embodiments described in the disclosure, for those of ordinary skill in the art, other drawings may be obtained based on these drawings without any creative work.

### Example 1

An encapsulant material for a photovoltaic module, the encapsulant material comprises: between 30 and 50 parts by weight of a fiber cloth, the fiber cloth being made of fiber material. Preferably, the fiber cloth can be made of fiber material in the form of plain weave, twill weave, satin weave, rib weave, mat weave, or a combination thereof. Specifically, in this example, 30 parts by weight of fiber cloth are employed, and the fiber cloth is made of fiber material in the form of plain weave. Optionally, one of ordinary skilled in the art can select other weaving methods according to actual needs.

Preferably, in this example, the weight per unit area of the fiber cloth can be 30-400 g/m², which can ensure the lightweight and the strength of the fiber cloth. Specifically, in this example, the weight per unit area of the fiber cloth can be 100 g/m².

Preferably, in this example, the fiber material can be glass fiber, carbon fiber, aramid fiber, or a mixture thereof, to ensure that the fiber cloth has good insulation and weather resistance. Specifically, in this example, the fiber material is glass fiber. Optionally, one of ordinary skilled in the art can select other types of fiber materials according to actual needs, and the embodiments of the disclosure will not describe this one by one.

Preferably, the monofilament diameter of the fiber material is between 3 and 23 μm. Specifically, in this example, the monofilament diameter of the fiber material is 3 μm. This facilitates the weaving of the fiber material and is conducive to preparation of the fiber cloth having the desired weight per unit area.

The encapsulant material further comprises between 50 and 70 parts by weight of a polyester powder coating. The polyester powder coating comprises a polyester resin and a curing agent. Specifically, in this example, 70 parts by weight of the polyester powder coating are employed.

Preferably, in this example, the polyester resin is a hydroxyl polyester resin, a carboxyl polyester resin, or a mixture thereof. This can ensure the polyester resin has good insulation and weather resistance. Preferably, the polyester resin is hydroxyl polyester resin.

Preferably, the hydroxyl polyester resin is a polymer of monomers selected from neopentyl glycol, adipic acid, ethylene glycol, or a mixture thereof. Optionally, one of ordinary skilled in the art can select other types of monomers to synthesize the hydroxyl polyester resin according to actual needs, and the embodiments of the disclosure will not describe this one by one. Preferably, the hydroxyl polyester resin is a polymer of adipic acid.

Preferably, in this example, the hydroxyl polyester resin comprising between 30 and 300 mg of KOH per gram of the hydroxyl polyester resin; a glass transition temperature of the hydroxyl polyester resin is between 50 and 75° C., and a viscosity of the hydroxyl polyester resin is between 15 and 200 Pa·s. Particularly, the hydroxyl polyester resin comprises 100 mg of KOH per gram of the hydroxyl polyester resin; a glass transition temperature of the hydroxyl polyester resin is 60° C., and a viscosity of the hydroxyl polyester resin is 80 Pa·s.

Preferably, in this example, the curing agent can account for 2-20 wt. % of the polyester powder coating, and the curing agent is 1,3,5-triglycidyl isocyanurate, triglycidyl trimellitate (TML), diglycidyl terephthalate, glycidyl methacrylate (GMA), hydroxyalkyl amide, isocyanate, or a mixture thereof. Specifically, in this example, the curing agent is 1,3,5-triglycidyl isocyanurate which accounts for 5 wt. % of the polyester powder coating. Optionally, one of ordinary skilled in the art can select other types of curing agent accounting for 2-20 wt. % (the end values 2% and 20% are included) of the polyester powder coating according to actual needs, and the same technical effect can be achieved. The embodiments of the disclosure will not describe this one by one.

The polyester powder coating is evenly distributed on the fiber cloth, and the weight per unit area of the polyester powder coating can be 100-400 g/m². Specifically, in this example, the weight per unit area of the polyester powder coating distributed on the fiber cloth is 100 g/m².

In certain examples, the polyester powder coating further comprises a coating additive. Preferably, the coating additive can account for 0-40 wt. % of the polyester powder coating, which is conducive to improving the insulation and weather resistance of the polyester powder coating. In addition, according to the actual installation requirements of the photovoltaic modules, the color of the polyester powder coating can be adjusted by adding the coating additive, which further benefits the practical installation and application of the photovoltaic module. Specifically, the coating additive is polyamide wax, polyolefine wax, amide modified phenolic urea surfactant, benzoin, poly(dimethylsiloxane), vinyl trichlorosilane, n-butyl triethoxyl silane, tetramethoxysilane (TMOS), monoalkoxy pyrophosphate, acrylics, phenolic resin, urea-formaldehyde resin, melamine formaldehyde resin, distearoyl ethylenediamine, a mixture of ethylene oxide and propylene oxide, hindered phenol, thiodipropionate, diphenyl ketone, salicylate derivatives, hindered amine, alumina, fumed silica, tetrabromobisphenol A, decabromodiphenyl ethane, tricresyl phosphate, aluminum hydroxide, magnesium hydroxide, barium sulfate, titanium dioxide, carbon black, or a mixture thereof in any ratio. Optionally, one of ordinary skilled in the art can select other types of coating additives according to actual needs, and the embodiments of the disclosure will not describe this one by one.

The polyester powder coating of the disclosure can be prepared using any of the known preparation techniques for powder coatings. Typical methods include premixing, melt extrusion, and milling. Specifically, in this example, the polyester resin is premixed with the curing agent, preferably, the premixing time is between 2 and 10 min (when the polyester powder coating comprises a coating additive, the coating additive can be premixed together). Thereafter, the premixed mixture is extruded and pressed into thin slices with a screw extruder. The aspect ratio of the extruder can be set at between 15:1 and 50:1. The screw extruder is heated to between 80 and 120° C., and rotates at 200-800 rpm. The thin slices are crushed into small pieces which are conveyed to a powder mill to be ground into a powder coating having certain particle sizes. Preferably, the rotational speed of the powder mill is 50-150 rpm. The particle size of the polyester powder coating is 35-300 μm. Optionally, the polyester powder coating can be prepared using other process parameters or preparation processes; these parameters or preparation processes are familiar to one of ordinary skill in the art, so the embodiments of the disclosure will not describe this in detail.

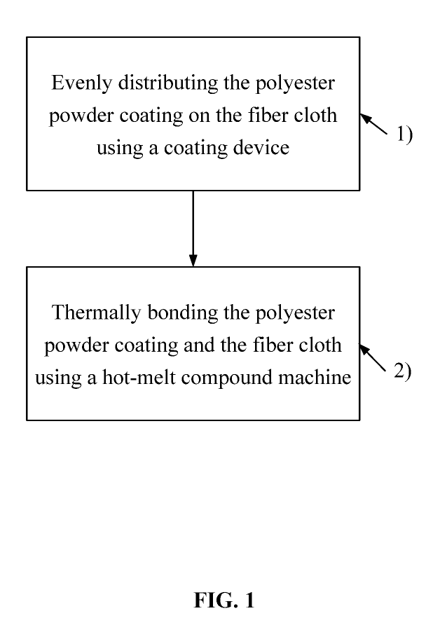

As shown in FIG. 1, a method of preparing an encapsulant material for a photovoltaic module comprises:

1) evenly distributing the polyester powder coating on the fiber cloth; and

2) thermally bonding the polyester powder coating and the fiber cloth.

The method further comprises piecewise cutting a resulting product obtained by thermally bonding the polyester powder coating and the fiber cloth in 2).

In this example, thermally bonding the polyester powder coating and the fiber cloth is achieved under appropriate pressure and heat. It is only under appropriate pressure and temperature that a thermal bonding can be achieved between the polyester powder coating and the fiber cloth, thus fulfilling the laminating requirement in the process of preparing the photovoltaic module, so as to prepare the encapsulant materials that can effectively apply to the encapsulant of the photovoltaic cell components. Preferably, during the thermal bonding, the pressure is between 0.05 and 0.25 megapascal, the temperature is between 90 and 130° C., and the heating time is between 5 and 20 seconds. Specifically, the pressure is 0.05 megapascal, the temperature is 130° C., and the heating time is 5 seconds.

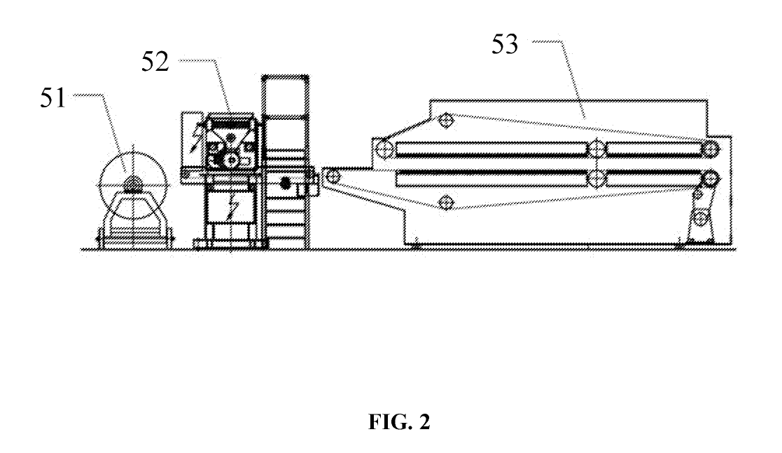

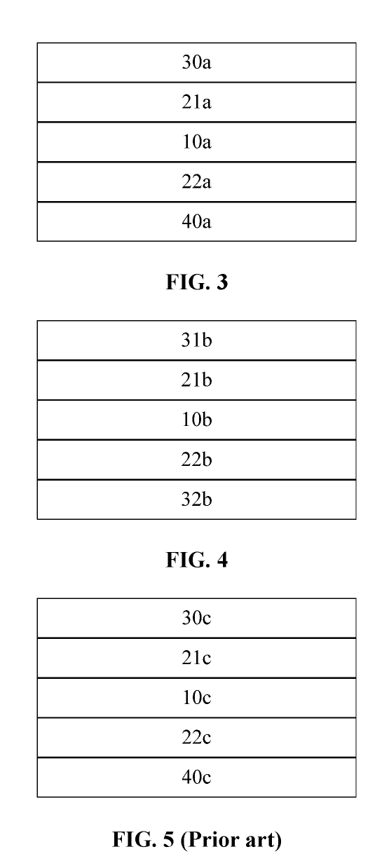

Preferably, FIG. 2 illustrates a device for preparing the encapsulant material for a photovoltaic module. In the production process, the fiber cloth is put into a fiber feeder 51, and then the polyester powder coating is evenly distributed on the fiber cloth output from the fiber feeder 51 by a coating device 52. Thereafter, the polyester powder coating and the fiber cloth are thermally bonded under the pressure and heat produced by a hot-melt compound machine 53. The thermally bonded polyester powder coating and the fiber cloth is piecewise cut, to yield an encapsulant material for a photovoltaic module. In other embodiments of the disclosure, the coating device can be a dusting head. The coating device implements the coating process in the form of powder dusting, and the polyester powder coating is evenly distributed on the fiber cloth. Optionally, one of ordinary skill in the art can select other known devices to prepare the encapsulant material for photovoltaic modules.

FIG. 3 illustrates an encapsulant structure of a photovoltaic module using the encapsulant material. The photovoltaic encapsulant structure comprises, from top to bottom, an encapsulant material layer 30a, an upper EVA layer 21a, a photovoltaic cell layer 10a, a lower EVA layer 22a, and a backsheet layer 40a. The encapsulant material layer 30a substitutes for conventional tempered glass layer. One of ordinary skill in the art may use the encapsulant material of the embodiment of the disclosure to replace other encapsulant structures or to replace other layer structures in combination with other materials according to the actual needs and the conditions of the installation site, and the disclosure does not make specific restrictions on this. FIG. 4 illustrates another encapsulant structure of a photovoltaic module using the encapsulant material. The photovoltaic encapsulant structure comprises, from top to bottom, an upper encapsulant material layer 31b, an upper EVA layer 21b, a photovoltaic cell layer 10b, a lower EVA layer 22b, and a lower encapsulant material layer 32b. The upper encapsulant material layer 31b and the lower encapsulant material layer 32b substitutes for conventional tempered glass layer and backsheet layer, respectively.

### Example 2

In this example, the encapsulant structure of a photovoltaic module comprises the following components:

35 parts by weight of fiber cloth; the fiber cloth is made of fiber material in the form of twill weave;

the weight per unit area of the fiber cloth is 30 g/m²;

the fiber material is carbon fiber;

the monofilament diameter of the fiber material is 5 μm;

65 parts by weight of polyester powder coating; the polyester powder coating comprising a polyester resin, a curing agent and a coating additive;

the polyester resin is a carboxyl polyester resin which is a polymer of monomers selected from terephthalic acid, m-phthalic acid, or a mixture thereof; the carboxyl polyester resin comprising between 15 and 85 mg of KOH per gram of the carboxyl polyester resin; a glass transition temperature of the carboxyl polyester resin is between 50 and 75° C., and a viscosity of the carboxyl polyester resin is between 15 and 200 Pa·s; specifically, the carboxyl polyester resin is a polymer of terephthalic acid, and comprises 85 mg of KOH per gram of the carboxyl polyester resin; a glass transition temperature of the carboxyl polyester resin is 75° C., and a viscosity of the carboxyl polyester resin is 200 Pa·s;

the curing agent is triglycidyl trimellitate (TML), which accounts for 6 wt. % of the polyester powder coating;

the coating additive is a mixture of polyamide wax, polyolefine wax, amide modified phenolic urea surfactant, benzoin, hindered phenol, thiodipropionate, diphenyl ketone, salicylate derivatives, hindered amine, alumina, magnesium hydroxide, barium sulfate, titanium dioxide, carbon black in any ratio, and accounts for 40 wt. % of the polyester powder coating;

the weight per unit area of the polyester powder coating distributed on the fiber cloth is 150 g/m²;

during the thermal bonding for preparing the encapsulant material, the pressure is 0.1 megapascal, the temperature is 120° C., and the heating time is 8 seconds;

other technical solutions in Example 2 are the same as that in Example 1.

### Example 3

In this example, the encapsulant structure of a photovoltaic module comprises the following components:

40 parts by weight of fiber cloth; the fiber cloth is made of fiber material in the form of satin weave;

the weight per unit area of the fiber cloth is 50 g/m²;

the fiber material is aramid fiber;

the monofilament diameter of the fiber material is 8 μm;

60 parts by weight of polyester powder coating; the polyester powder coating comprising a polyester resin, a curing agent and a coating additive;

the polyester resin is a polymer of monomers of neopentyl glycol;

the hydroxyl polyester resin comprises 30 mg of KOH per gram of the hydroxyl polyester resin; a glass transition temperature of the hydroxyl polyester resin is 50° C., and a viscosity of the hydroxyl polyester resin is 15 Pa·s;

the curing agent is diglycidyl terephthalate, which accounts for 8 wt. % of the polyester powder coating;

the coating additive is a mixture of poly(dimethylsiloxane), vinyl trichlorosilane, n-butyl triethoxyl silane, tetramethoxysilane (TMOS), monoalkoxy pyrophosphate, decabromodiphenyl ethane, tricresyl phosphate, aluminum hydroxide, barium sulfate in any ratio, and accounts for 35 wt. % of the polyester powder coating;

the weight per unit area of the polyester powder coating distributed on the fiber cloth is 200 g/m²;

during the thermal bonding for preparing the encapsulant material, the pressure is between 0.15 megapascal, the temperature is 100° C., and the heating time is 10 seconds;

other technical solutions in Example 3 are the same as that in Example 1.

### Example 4

In this example, the encapsulant structure of a photovoltaic module comprises the following components:

45 parts by weight of fiber cloth; the fiber cloth is made of fiber material in the form of rib weave;

the weight per unit area of the fiber cloth is 80 g/m²;

the monofilament diameter of the fiber material is 10 μm;

55 parts by weight of polyester powder coating; the polyester powder coating comprising a polyester resin, a curing agent and a coating additive;

the polyester resin is a polymer of monomers of ethylene glycol;

the hydroxyl polyester resin comprises 50 mg of KOH per gram of the hydroxyl polyester resin; a glass transition temperature of the hydroxyl polyester resin is 55° C., and a viscosity of the hydroxyl polyester resin is 35 Pa·s;

the curing agent is diglycidyl terephthalate, which accounts for 8 wt. % of the polyester powder coating;

the coating additive is a mixture of hindered phenol, thiodipropionate, diphenyl ketone, salicylate derivatives, hindered amine, alumina, barium sulfate in any ratio, and accounts for 30 wt. % of the polyester powder coating;

the weight per unit area of the polyester powder coating distributed on the fiber cloth is 250 g/m²;

during the thermal bonding for preparing the encapsulant material, the pressure is between 0.18 megapascal, the temperature is 115° C., and the heating time is 8 seconds;

other technical solutions in Example 4 are the same as that in Example 1.

### Example 5

In this example, the encapsulant structure of a photovoltaic module comprises the following components:

50 parts by weight of fiber cloth; the fiber cloth is made of fiber material in the form of mat weave;

the weight per unit area of the fiber cloth is 120 g/m²;

the monofilament diameter of the fiber material is 13 μm;

50 parts by weight of polyester powder coating; the polyester powder coating comprising a polyester resin, a curing agent and a coating additive;

the polyester resin is a polymer of monomers of neopentyl glycol and adipic acid;

the hydroxyl polyester resin comprises 80 mg of KOH per gram of the hydroxyl polyester resin; a glass transition temperature of the hydroxyl polyester resin is 58° C., and a viscosity of the hydroxyl polyester resin is 70 Pa·s;

the curing agent is glycidyl methacrylate (GMA), which accounts for 10 wt. % of the polyester powder coating;

the coating additive is a mixture of melamine formaldehyde resin, distearoyl ethylenediamine, a mixture of ethylene oxide and propylene oxide, hindered phenol, thiodipropionate, and diphenyl ketone, and accounts for 20 wt. % of the polyester powder coating;

the weight per unit area of the polyester powder coating distributed on the fiber cloth is 300 g/m²;

during the thermal bonding for preparing the encapsulant material, the pressure is between 0.2 megapascal, the temperature is 118° C., and the heating time is 6 seconds;

other technical solutions in Example 5 are the same as that in Example 1.

### Example 6

In this example, the encapsulant structure of a photovoltaic module comprises the following components:

38 parts by weight of fiber cloth; the fiber cloth is made of fiber material in the form of hybrid of plain weave and twill weave;

the weight per unit area of the fiber cloth is 150 g/m²;

the monofilament diameter of the fiber material is 16 μm;

62 parts by weight of polyester powder coating; the polyester powder coating comprising a polyester resin, a curing agent and a coating additive;

the polyester resin is a polymer of monomers of adipic acid and ethylene glycol;

the hydroxyl polyester resin comprises 150 mg of KOH per gram of the hydroxyl polyester resin; a glass transition temperature of the hydroxyl polyester resin is 65° C., and a viscosity of the hydroxyl polyester resin is 100 Pa·s;

the curing agent is isocyanate, which accounts for 12 wt. % of the polyester powder coating;

the coating additive is a mixture of polyamide wax, phenolic resin, ethylene oxide, propylene oxide, and magnesium hydroxide in any ratio, and accounts for 35 wt. % of the polyester powder coating;

the weight per unit area of the polyester powder coating distributed on the fiber cloth is 350 g/m²;

during the thermal bonding for preparing the encapsulant material, the pressure is between 0.25 megapascal, the temperature is 95° C., and the heating time is 15 seconds;

other technical solutions in Example 6 are the same as that in Example 1.

### Example 7

In this example, the encapsulant structure of a photovoltaic module comprises the following components:

33 parts by weight of fiber cloth; the fiber cloth is made of fiber material in the form of hybrid of plain weave and satin weave;

the weight per unit area of the fiber cloth is 180 g/m²;

the monofilament diameter of the fiber material is 18 μm;

67 parts by weight of polyester powder coating; the polyester powder coating comprising a polyester resin, a curing agent and a coating additive;

the polyester resin is a polymer of monomers of adipic acid and ethylene glycol;

the hydroxyl polyester resin comprises 200 mg of KOH per gram of the hydroxyl polyester resin; a glass transition temperature of the hydroxyl polyester resin is 70° C., and a viscosity of the hydroxyl polyester resin is 150 Pa·s;

the curing agent is isocyanate, which accounts for 15 wt. % of the polyester powder coating;

the coating additive is a mixture of vinyl trichlorosilane, n-butyl triethoxyl silane, tetramethoxysilane (TMOS), monoalkoxy pyrophosphate in any ratio, and accounts for 8 wt. % of the polyester powder coating;

the weight per unit area of the polyester powder coating distributed on the fiber cloth is 400 g/m²;

during the thermal bonding for preparing the encapsulant material, the pressure is between 0.22 megapascal, the temperature is 105° C., and the heating time is 20 seconds;

other technical solutions in Example 7 are the same as that in Example 1.

### Example 8

In this example, the encapsulant structure of a photovoltaic module comprises the following components:

42 parts by weight of fiber cloth; the fiber cloth is made of fiber material in the form of hybrid of plain weave and satin weave;

the weight per unit area of the fiber cloth is 200 g/m²;

the monofilament diameter of the fiber material is 18 μm;

58 parts by weight of polyester powder coating; the polyester powder coating comprising a polyester resin, a curing agent and a coating additive;

the carboxyl polyester resin comprises 35 mg of KOH per gram of the carboxyl polyester resin; a glass transition temperature of the carboxyl polyester resin is 72° C., and a viscosity of the carboxyl polyester resin is 180 Pa·s;

the curing agent is 1,3,5-triglycidyl isocyanurate, which accounts for 10 wt. % of the polyester powder coating;

the coating additive is a mixture of acrylics, phenolic resin, urea-formaldehyde resin, melamine formaldehyde resin in any ratio, and accounts for 5 wt. % of the polyester powder coating;

during the thermal bonding for preparing the encapsulant material, the pressure is between 0.16 megapascal, the temperature is 98° C., and the heating time is 18 seconds;

other technical solutions in Example 8 are the same as that in Example 1.

### Example 9

In this example, the encapsulant structure of a photovoltaic module comprises the following components:

48 parts by weight of fiber cloth; the fiber cloth is made of fiber material in the form of hybrid of satin weave and rib weave;

the weight per unit area of the fiber cloth is 250 g/m²;

the fiber material is carbon fiber;

the monofilament diameter of the fiber material is 20 μm;

52 parts by weight of polyester powder coating; the polyester powder coating comprising a polyester resin, a curing agent and a coating additive;

the polyester resin is a polymer of monomers of m-phthalic acid;

the carboxyl polyester resin comprises 30 mg of KOH per gram of the carboxyl polyester resin; a glass transition temperature of the carboxyl polyester resin is 70° C., and a viscosity of the carboxyl polyester resin is 150 Pa·s;

the curing agent accounts for 5 wt. % of the polyester powder coating;

during the thermal bonding for preparing the encapsulant material, the pressure is between 0.18 megapascal, the temperature is 100° C., and the heating time is 16 seconds;

other technical solutions in Example 9 are the same as that in Example 2.

### Example 10

In this example, the encapsulant structure of a photovoltaic module comprises the following components:

46 parts by weight of fiber cloth; the fiber cloth is made of fiber material in the form of hybrid of plain weave, twill weave, and mat weave;

the weight per unit area of the fiber cloth is 300 g/m²;

the fiber material is a mixture of glass fiber and aramid fiber;

the monofilament diameter of the fiber material is 23 μm;

54 parts by weight of polyester powder coating; the polyester powder coating comprising a polyester resin, a curing agent and a coating additive;

the polyester resin is a polymer of monomers of m-phthalic acid; the carboxyl polyester resin comprises 60 mg of KOH per gram of the carboxyl polyester resin; a glass transition temperature of the carboxyl polyester resin is 65° C., and a viscosity of the carboxyl polyester resin is 120 Pa·s;

the curing agent accounts for 8 wt. % of the polyester powder coating;

other technical solutions in Example 10 are the same as that in Example 2.

### Example 11

In this example, the encapsulant structure of a photovoltaic module comprises the following components:

36 parts by weight of fiber cloth; the fiber cloth is made of fiber material in the form of hybrid of plain weave, twill weave, and mat weave;

the weight per unit area of the fiber cloth is 350 g/m²;

the fiber material is a mixture of glass fiber and carbon fiber;

the monofilament diameter of the fiber material is 14 μm;

64 parts by weight of polyester powder coating; the polyester powder coating comprising a polyester resin, a curing agent and a coating additive;

the polyester resin is a polymer of monomers of terephthalic acid and m-phthalic acid;

the carboxyl polyester resin comprises 50 mg of KOH per gram of the carboxyl polyester resin; a glass transition temperature of the carboxyl polyester resin is 62° C., and a viscosity of the carboxyl polyester resin is 80 Pa·s;

the curing agent accounts for 10 wt. % of the polyester powder coating;

other technical solutions in Example 11 are the same as that in Example 2.

### Example 12

In this example, the encapsulant structure of a photovoltaic module comprises the following components:

35 parts by weight of fiber cloth; the fiber cloth is made of fiber material in the form of hybrid of plain weave, twill weave, and mat weave;

the weight per unit area of the fiber cloth is 400 g/m²;

the monofilament diameter of the fiber material is 23 μm;

65 parts by weight of polyester powder coating; the polyester powder coating comprising a polyester resin, a curing agent and a coating additive;

the polyester resin is a polymer of monomers of terephthalic acid and m-phthalic acid;

the carboxyl polyester resin comprises 30 mg of KOH per gram of the carboxyl polyester resin; a glass transition temperature of the carboxyl polyester resin is 58° C., and a viscosity of the carboxyl polyester resin is 60 Pa·s

the curing agent accounts for 14 wt. % of the polyester powder coating;

other technical solutions in Example 12 are the same as that in Example 2.

### Example 13

In this example, the technical solutions are the same as that in Example 1 except that, in this example, the weight per unit area of the fiber cloth is 130 g/m²; and the weight per unit area of the polyester powder coating distributed on the fiber cloth is 180 g/m².

### Example 14

In this example, the technical solutions are the same as that in Example 2 except that, in this example, the carboxyl polyester resin comprises 15 mg of KOH per gram of the carboxyl polyester resin; a glass transition temperature of the carboxyl polyester resin is 50° C., and a viscosity of the carboxyl polyester resin is 15 Pa·s; the curing agent accounts for 16 wt. % of the polyester powder coating; the weight per unit area of the fiber cloth is 80 g/m²; and the weight per unit area of the polyester powder coating distributed on the fiber cloth is 280 g/m².

### Comparison Example 1

The encapsulant material in this example is a typical encapsulant material as described in the background.

### Comparison Example 2

The encapsulant material in this example employs an ethylene-vinyl acetate (EVA) copolymer adhesive film as described in the background.

### Comparison Example 3

The encapsulant material in this example employs poly(octene-ethylene) (POE) adhesive film as described in the background.

### Comparison Example 4

In this example, the technical solutions are the same as that in Example 1 except that, in this example, the encapsulant material comprises 30 parts by weight of fiber cloth and commercial epoxy powder coatings.

The comparisons of the implementation effect of the encapsulant materials in the examples and the comparison examples of the disclosure are listed in Table 1:

TABLE 1
Comparisons of implementation effect of the encapsulant materials in
the examples and the comparison examples of the disclosure

| | Weight of | Impact resistance | | |
|---|---|---|---|---|
| | encapsulant | | Maximum power | Insulation |
| Test items | structure | Appearance | degradation | resistance |
| Example 1 | ≤1 kg/m², easy to | No defects | ≤5% | ≥40 MΩ · m² |
| | install | | | |
| Example 2 | ≤1 kg/m², easy to | No defects | ≤5% | ≥40 MΩ · m² |
| | install | | | |
| Example 3 | ≤1 kg/m², easy to | No defects | ≤5% | ≥40 MΩ · m² |
| | install | | | |
| Example 4 | ≤1 kg/m², easy to | No defects | ≤5% | ≥40 MΩ · m² |
| | install | | | |
| Example 5 | ≤1 kg/m², easy to | No defects | ≤5% | ≥40 MΩ · m² |
| | install | | | |
| Example 6 | ≤1 kg/m², easy to | No defects | ≤5% | ≥40 MΩ · m² |
| | install | | | |
| Example 7 | ≤1 kg/m², easy to | No defects | ≤5% | ≥40 MΩ · m² |
| | install | | | |
| Example 8 | ≤1 kg/m², easy to | No defects | ≤5% | ≥40 MΩ · m² |
| | install | | | |
| Example 9 | ≤1 kg/m², easy to | No defects | ≤5% | ≥40 MΩ · m² |
| | install | | | |
| Example 10 | ≤1 kg/m², easy to | No defects | ≤5% | ≥40 MΩ · m² |
| | install | | | |
| Example 11 | ≤1 kg/m², easy to | No defects | ≤5% | ≥40 MΩ · m² |
| | install | | | |
| Example 12 | ≤1 kg/m², easy to | No defects | ≤5% | ≥40 MΩ · m² |
| | install | | | |
| Example 13 | ≤1 kg/m², easy to | No defects | ≤5% | ≥40 MΩ · m² |
| | install | | | |
| Example 14 | ≤1 kg/m², easy to | No defects | ≤5% | ≥40 MΩ · m² |
| | install | | | |
| Comparison example 1 | ≥8 kg/m², difficult | No defects | ≤5% | ≥40 MΩ · m² |
| | to install | | | |
| Comparison example 2 | ≤1 kg/m², easy to | No defects | >5% | <40 MΩ · m² |
| | install | | | |
| Comparison example 3 | ≤1 kg/m², easy to | No defects | >5% | <40 MΩ · m² |
| | install | | | |
| Comparison example 4 | ≤1 kg/m², easy to | No defects | ≤5% | ≥40 MΩ · m² |
| | install | | | |

| | | Pencil | Tensile | Elongation | Weathering |
|---|---|---|---|---|---|
| Test items | Fire resistance | hardness | strength | at break | test |
| Example 1 | Self-extinguishing, | 1H satisfied | 25-35 | 150-250% | Successful |
| | non-combustion | | megapascal | | |
| Example 2 | Self-extinguishing, | 1H satisfied | 25-35 | 150-250% | Successful |
| | non-combustion | | megapascal | | |
| Example 3 | Self-extinguishing, | 1H satisfied | 25-35 | 150-250% | Successful |
| | non-combustion | | megapascal | | |
| Example 4 | Self-extinguishing, | 1H satisfied | 25-35 | 150-250% | Successful |
| | non-combustion | | megapascal | | |
| Example 5 | Self-extinguishing, | 1H satisfied | 25-35 | 150-250% | Successful |
| | non-combustion | | megapascal | | |
| Example 6 | Self-extinguishing, | 1H satisfied | 25-35 | 150-250% | Successful |
| | non-combustion | | megapascal | | |
| Example 7 | Self-extinguishing, | 1H satisfied | 25-35 | 150-250% | Successful |
| | non-combustion | | megapascal | | |
| Example 8 | Self-extinguishing, | 1H satisfied | 25-35 | 150-250% | Successful |
| | non-combustion | | megapascal | | |
| Example 9 | Self-extinguishing, | 1H satisfied | 25-35 | 150-250% | Successful |
| | non-combustion | | megapascal | | |
| Example 10 | Self-extinguishing, | 1H satisfied | 25-35 | 150-250% | Successful |
| | non-combustion | | megapascal | | |
| Example 11 | Self-extinguishing, | 1H satisfied | 25-35 | 150-250% | Successful |
| | non-combustion | | megapascal | | |
| Example 12 | Self-extinguishing, | 1H satisfied | 25-35 | 150-250% | Successful |
| | non-combustion | | megapascal | | |
| Example 13 | Self-extinguishing, | 1H satisfied | 25-35 | 150-250% | Successful |
| | non-combustion | | megapascal | | |
| Example 14 | Self-extinguishing, | 1H satisfied | 25-35 | 150-250% | Successful |
| | non-combustion | | megapascal | | |
| Comparison | Self-extinguishing, | 1H satisfied | 42 | 2-3% | Successful |
| example 1 | non-combustion | | megapascal | | |
| Comparison | Combustible | 1H, | 16 | 550% | Successful |
| example 2 | | unsatisfied | megapascal | | |
| Comparison | Combustible | 1H, | 18 | 350% | Successful |
| example 3 | | unsatisfied | megapascal | | |
| Comparison | Self-extinguishing, | 1H satisfied | 80-90 | 50-70% | Failed |
| example 4 | non-combustion | | megapascal | | |

The weight of the encapsulant structure in the disclosure refers to the weight per unit square meter of the encapsulant material of the PV module. The impact resistance test is implemented as follows: an ice hockey with the standard diameter of 25 mm and the mass of 7.53 g is launched at the speed of 23.0 m/s to impact eleven positions of the packaged photovoltaic module, and then the impact resistance of the photovoltaic module is judged by the appearance, the maximum power degradation and the insulation resistance. The fire resistance is measured according to the UL1703 standard. The pencil hardness is measured according to the ASTM D3363-2005 (R2011) standard. The tensile strength is measured according to the GB/T 1040.3-2006 standard. The elongation at break is measured according to the GB/T 1040.3-2006 standard.

Based on the test data in Table 1, the encapsulant material meets the technical standards of the photovoltaic industry such as UV resistance, anti-aging, impact resistance, fire prevention and the like, and is inexpensive, light-weighted, can replace the tempered glass of conventional encapsulant structure, and provide rigidity for the photovoltaic module to protect the photovoltaic cells. Thus, the weight of the photovoltaic module is greatly reduced, which facilitates the installation of the photovoltaic module in different occasions, reduces the labor intensity for installing the photovoltaic module, improves the convenience of installation, and reduces the installation cost of the photovoltaic module.

In addition, the preparation method of the encapsulant material comprises evenly distributing the polyester powder coating on the fiber cloth, thermally bonding the polyester powder coating and the fiber cloth, and then piecewise cutting the thermally bonded polyester powder coating and the fiber cloth, to yield the encapsulant material. The dimensions of the PV module can be changed arbitrarily to meet the installation requirements of different buildings, which further facilitates the installation and application of the PV module.

Although the encapsulant material taught in this disclosure can be applied to the encapsulant of the photovoltaic modules with excellent implementation effect, the photovoltaic field is not the only application field of the material. One of ordinary in the art should apply the encapsulant material to other suitable fields, according to the actual needs and the characteristics and the actual performance of the encapsulant material of the disclosure, which involves no creative work and still belongs to the spirit of the disclosure, so such an application is also considered to be as the scope of the protection of the rights of the disclosure.

For those skilled in the art, it is clear that the invention is not limited to the details of the above exemplary embodiments, and that the invention can be realized in other specific forms without departing from the spirit or basic characteristics of the invention. Therefore, at any point, the implementation should be regarded as exemplary and unrestrictive, and the scope of the invention is defined by the appended claims rather than the above description, and therefore aims to include all the changes within the meaning and scope of the equivalent elements of the claim. Any appended drawing reference signs in the claims shall not be regarded as restrictions on the claims.

Unless otherwise indicated, the numerical ranges involved include the beginning and end values. It will be obvious to those skilled in the art that changes and modifications may be made, and therefore, the aim in the appended claims is to cover all such changes and modifications.

What is claimed is:

1. A material, comprising:
between 30 and 50 parts by weight of a fiber cloth; and
between 50 and 70 parts by weight of a polyester powder coating, the polyester powder coating comprising a polyester resin and a curing agent, and the polyester powder coating being evenly distributed on the fiber cloth.

2. The material of claim 1, wherein a weight per unit area of the fiber cloth is between 30 and 400 g/m², and a weight per unit area of the polyester powder coating distributed on the fiber cloth is between 100 and 400 g/m².

3. The material of claim 1, wherein the fiber cloth comprises a fiber material selected from glass fiber, carbon fiber, aramid fiber, or a mixture thereof.

4. The material of claim 3, wherein a monofilament diameter of the fiber material is between 3 and 23 μm.

5. The material of claim 3, wherein the fiber cloth is in the form of a plain weave, a twill weave, a satin weave, a rib weave, a mat weave, or a combination thereof.

6. The material of claim 1, wherein the polyester resin is a hydroxyl polyester resin, a carboxyl polyester resin, or a mixture thereof.

7. The material of claim 6, wherein the polyester resin is a polymer of monomers selected from terephthalic acid, m-phthalic acid, neopentyl glycol, adipic acid, ethylene glycol, or a mixture thereof.

8. The material of claim 6, wherein the polyester resin is a hydroxyl polyester resin comprising between 30 and 300 mg of KOH per gram of the hydroxyl polyester resin; a glass transition temperature of the hydroxyl polyester resin is between 50 and 75° C., and a viscosity of the hydroxyl polyester resin is between 15 and 200 Pa·s.

9. The material of claim 6, wherein the polyester resin is a carboxyl polyester resin comprising between 15 and 85 mg of KOH per gram of the carboxyl polyester resin; a glass transition temperature of the carboxyl polyester resin is between 50 and 75° C., and a viscosity of the carboxyl polyester resin is between 15 and 200 Pa·s.

10. The material of claim 1, wherein the curing agent accounts for 2-20 wt. % of the polyester powder coating, and the curing agent is 1,3,5-triglycidyl isocyanurate, triglycidyl trimellitate (TML), diglycidyl terephthalate, glycidyl methacrylate (GMA), hydroxyalkyl amide, isocyanate, or a mixture thereof.

11. The material of claim 10, wherein the polyester powder coating further comprises a coating additive; the coating additive accounts for 0-40 wt. % of the polyester powder coating, and the coating additive is polyamide wax, polyolefine wax, amide modified phenolic urea surfactant, benzoin, poly(dimethylsiloxane), vinyl trichlorosilane, n-butyl triethoxyl silane, tetramethoxysilane (TMOS), monoalkoxy pyrophosphate, acrylics, phenolic resin, urea-formaldehyde resin, melamine formaldehyde resin, distearoyl ethylenediamine, a mixture of ethylene oxide and propylene oxide, hindered phenol, thiodipropionate, diphenyl ketone, salicylate derivatives, hindered amine, alumina, fumed silica, tetrabromobisphenol A, decabromodiphenyl ethane, tricresyl phosphate, aluminum hydroxide, magnesium hydroxide, barium sulfate, titanium dioxide, carbon black, or a mixture thereof.

12. A method of preparing a material of claim 1, the method comprising:
1) evenly distributing the polyester powder coating on the fiber cloth using a coating device; and
2) thermally bonding the polyester powder coating and the fiber cloth.

13. The method of claim 12, further comprising piecewise cutting a resulting product obtained by thermally bonding the polyester powder coating and the fiber cloth in 2).

14. The method of claim 12, wherein thermally bonding the polyester powder coating and the fiber cloth is implemented with the following parameters: a pressure is between 0.05 and 0.25 megapascal, a temperature is between 90 and 130° C., and a heating time is between 5 and 20 seconds.

15. The method of claim 12, wherein a weight per unit area of the fiber cloth is between 30 and 400 g/m², and a weight per unit area of the polyester powder coating distributed on the fiber cloth is between 100 and 400 g/m².

16. The method of claim 12, wherein the polyester resin is a hydroxyl polyester resin, a carboxyl polyester resin, or a mixture thereof.

17. The method of claim 16, wherein the curing agent accounts for 2-20 wt. % of the polyester powder coating, and the curing agent is 1,3,5-triglycidyl isocyanurate, triglycidyl trimellitate (TML), diglycidyl terephthalate, glycidyl methacrylate (GMA), hydroxyalkyl amide, isocyanate, or a mixture thereof.

18. The method of claim 12, wherein the polyester resin is a polymer of monomers selected from terephthalic acid, m-phthalic acid, neopentyl glycol, adipic acid, ethylene glycol, or a mixture thereof.

19. The method of claim 12, wherein the polyester resin is a hydroxyl polyester resin comprising between 30 and 300 mg KOH per gram of the hydroxyl polyester resin, a glass transition temperature of the hydroxyl polyester resin is between 50 and 75° C., and a viscosity of the hydroxyl polyester resin is between 15 and 200 Pa·s.

20. The method of claim 12, wherein the polyester resin is a carboxyl polyester resin comprising between 15 and 85 mg KOH per gram of the carboxyl polyester resin; a glass transition temperature of the carboxyl polyester resin is between 50 and 75° C., and a viscosity of the carboxyl polyester resin is between 15 and 200 Pa·s.
